(19) United States
(12) Patent Application Publication
(10) Pub. No.: US 2025/0305972 A1
(43) Pub. Date: Oct. 2, 2025

(54) ELECTRON BEAM MASK INSPECTION APPARATUS

(71) Applicant: NuFlare Technology, Inc., Yokohama-shi (JP)

(72) Inventors: Atsushi ANDO, Edogawa-ku (JP); Munehiro OGASAWARA, Hiratsuka-shi (JP); Kazuhiko INOUE, Yokohama-shi (JP); Toshiaki OTAKI, Yokohama-shi (JP)

(73) Assignee: NuFlare Technology, Inc., Yokohama-shi (JP)

(21) Appl. No.: 19/235,751

(22) Filed: Jun. 12, 2025

Related U.S. Application Data
(63) Continuation of application No. PCT/JP2023/044091, filed on Dec. 8, 2023.

(30) Foreign Application Priority Data
Dec. 21, 2022 (JP) 2022-204144

(51) Int. Cl. G01N 23/2251

(52) U.S. Cl. CPC G01N 23/2251; G01N 2223/323; G01N 2223/611; G01N 2223/6462

(57) ABSTRACT

According to one aspect of the present invention, an electron beam mask inspection apparatus, includes: a first electrode plate in which an opening is formed, arranged between an objective lens and a mask substrate, an electron beam passing through the opening; a mark arranged above a stage so as to be spaced apart from the mask substrate and having a figure pattern formed on its surface; and a second electrode plate arranged at a height position lower than the first electrode plate and equal to or higher than a height position of the surface of the mask substrate, the second electrode plate being arranged so as to cover a gap between the mask substrate and the mark, wherein a same potential as the first potential applied to the surface of the mask substrate is applied to the first electrode plate, the mark, and the second electrode plate.

### CROSS-REFERENCE TO RELATED APPLICATION

This application is a continuation application based upon and claims the benefit of priority from prior Japanese Patent Application No. 2022-204144 (application number) filed on Dec. 21, 2022 in Japan, and International Application PCT/JP2023/044091, the International Filing Date of which is Dec. 8, 2023. The contents described in JP2022-204144 and PCT/JP2023/044091 are incorporated herein by reference.

### BACKGROUND OF THE INVENTION

### Field of the Invention

One aspect of the present invention relates to an electron beam mask inspection apparatus. For example, the invention relates to an inspection apparatus that inspects a pattern formed on a mask substrate using an image obtained by detecting a secondary electron beam resulting from emission of a primary electron beam.

### Related Art

In recent years, with the increase in the integration and capacity of a large-scale integrated circuit (LSI), the circuit pattern linewidth required for semiconductor devices has become narrower and narrower. In addition, improving the yield is indispensable for manufacturing the LSI, which requires a high manufacturing cost. However, as represented by 1-gigabit class DRAM (random access memory), the patterns configuring the LSI are on the order of submicron to nanometer. It is necessary to inspect defects in patterns, which are formed on a mask substrate that serves as a master for LSI patterns formed on a semiconductor wafer, with high accuracy. For this reason, it is necessary to capture a high-precision image.

In the inspection apparatus, for example, a substrate to be inspected is scanned with multiple primary electron beams using electron beams, and multiple secondary electron beams emitted from the substrate to be inspected are separated from the trajectories of the multiple primary electron beams. Then, the multiple secondary electron beams are detected by a detector to capture a pattern image.

In image acquisition using an electron beam, there is an optimum landing energy of the electron beam depending on the yield of electrons that are generated secondarily due to emission of a primary electron beam to a mask substrate to be inspected. For this reason, a retarding potential is applied to the mask substrate. When a retarding potential is applied to the mask substrate, a potential difference occurs between the mask substrate and the bottom surface of the electron optical column, generating an electric field. On the other hand, the retarding potential is applied to the outer periphery of the mask substrate from the surface side of the mask substrate. For this reason, a structure for applying a retarding potential to the surface of the mask substrate is arranged on the mask substrate. This has caused a problem that the electric field is disturbed to change the trajectory of the electron beam and reduce the inspection accuracy.

Here, a technique is disclosed in which a shield electrode having the same potential as the retarding voltage of a target object is provided in the vicinity above the target object to reduce disturbances in the electric field near the target object (see Published Unexamined Japanese Patent Application No. 2004-079516, for example).

However, providing a shield electrode having the same potential as the retarding voltage causes another problem. The inspection apparatus requires calibration of the electron beam. Such a beam calibration operation is performed, for example, multiple times while an image of one target object is being acquired. The beam calibration operation is performed by irradiating a mark arranged at a position separate from the target object with an electron beam. Therefore, the stage is moved to a position where the mark is within the emission range of the electron beam. During such movement, there is a problem in that discharge may occur between the shield electrode and the stage or a structure on the stage.

### BRIEF SUMMARY OF THE INVENTION

According to one aspect of the present invention, an electron beam mask inspection apparatus, includes:
a stage, a mask substrate being placed above the stage;
a substrate cover electrode arranged on the mask substrate so as to cover at least a part of an outer periphery of the mask substrate, the substrate cover electrode applying a first potential to the mask substrate from a surface side of the mask substrate;
an objective lens having a surface facing the mask substrate controlled to have a second potential different from the first potential, the objective lens guiding an electron beam onto the mask substrate;
a first electrode plate in which an opening is formed, arranged between the objective lens and the mask substrate, the electron beam passing through the opening;
a mark arranged above the stage so as to be spaced apart from the mask substrate and having a figure pattern formed on its surface; and
a second electrode plate arranged at a height position lower than the first electrode plate and equal to or higher than a height position of the surface of the mask substrate, the second electrode plate being arranged so as to cover a gap between the mask substrate and the mark,
wherein a same potential as the first potential applied to the surface of the mask substrate is applied to the first electrode plate, the mark, and the second electrode plate.

### BRIEF DESCRIPTION OF THE DRAWINGS

FIG. 1 is a configuration diagram showing the configuration of a pattern inspection apparatus according to Embodiment 1;

FIG. 2 is a conceptual diagram showing the configuration of a shaping aperture array substrate in Embodiment 1;

FIG. 3 is a diagram for explaining image acquisition processing in Embodiment 1;

FIG. 4 is a diagram showing an example of the configuration of the vicinity of arrangement positions of a substrate and a mark in Embodiment 1;

FIG. 5 is a diagram showing an example of a moving path of the central axis of an electron optics on a stage in Embodiment 1;

FIG. 6 is a diagram showing another example of the configuration of the vicinity of arrangement positions of the substrate and the mark in Embodiment 1;

FIG. 7 is a diagram showing another example of the configuration of the vicinity of arrangement positions of the substrate and the mark in Embodiment 1;

FIG. 8 is a diagram for explaining the size of a shield electrode plate in Embodiment 1;

FIG. 9 is a diagram showing an example of the relationship between an off-axis distance and a distance from the outer peripheral edge of the shield electrode plate to the central axis of the electron optics in Embodiment 1;

FIG. 10 is a diagram showing an example of the relationship between a distance r2 from the outer peripheral edge of the shield electrode plate to the central axis of the electron optics at a desired off-axis distance and a distance g between the shield electrode plate and the lower surface of the nearest member having a ground potential in Embodiment 1;

FIG. 11 is a diagram showing an example of the upper surface of a mark in Embodiment 1;

FIG. 12 is a top view showing an example of a substrate cover electrode in Embodiment 1;

FIG. 13 is a diagram showing an example of a state in which a substrate cover electrode is arranged on a substrate in Embodiment 1;

FIG. 14 is a cross-sectional view showing an example of a state in which a substrate cover electrode is arranged on a substrate on the long side of an inspection region in Embodiment 1;

FIG. 15 is a cross-sectional view showing another example of the state in which the substrate cover electrode is arranged on the substrate on the long side of the inspection region in Embodiment 1;

FIG. 16 is a cross-sectional view showing an example of a state in which the substrate cover electrode is arranged on the substrate on the short side of the inspection region in Embodiment 1; and

FIG. 17 is a configuration diagram showing an example of the internal configuration of a comparison circuit in Embodiment 1.

### DETAILED DESCRIPTION OF THE INVENTION

In the following embodiment, an apparatus is provided that can reduce disturbances in the electric field at the outer periphery of a target object and suppress discharge during beam calibration.

In the following embodiment, a multi-electron beam inspection apparatus using multiple electron beams will be described as an example of an electron beam mask inspection apparatus. However, the electron beam is not limited to multiple beams, and may be a single beam. In addition, the following configuration may be applied to any image acquisition apparatus other than the inspection apparatus, which acquires an image of a mask by irradiating the mask with an electron beam and detecting secondary electrons from the mask.

### EMBODIMENT 1

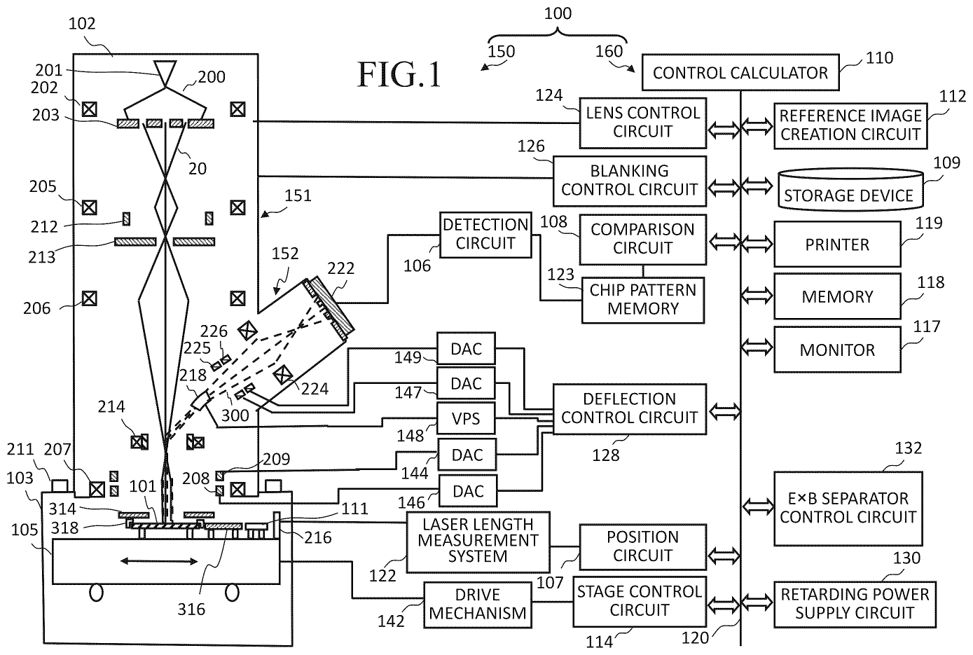

FIG. 1 is a configuration diagram showing the configuration of a pattern inspection apparatus according to Embodiment 1. In FIG. 1, an inspection apparatus 100 for inspecting a pattern formed on a mask substrate is an example of a multi-electron beam inspection apparatus. The inspection apparatus 100 is an example of a multi-electron beam image acquisition apparatus. The inspection apparatus 100 includes an image acquisition mechanism 150 and a control system circuit 160 (control unit). The image acquisition mechanism 150 includes an electron beam column 102 (electron optical column), an inspection room 103, a detection circuit 106, a chip pattern memory 123, a stage drive mechanism 142, and a laser length measurement system 122. An electron emission source 201, an illumination lens 202, a shaping aperture array substrate 203, an electromagnetic lens 205, a batch deflector 212, a limiting aperture substrate 213, an electromagnetic lens 206, an E×B separator 214 (separator), deflectors 208 and 209, an electromagnetic lens 207 (objective lens), a shield electrode plate 314, a deflector 218, deflectors 225 and 226, an electromagnetic lens 224, and a multi-detector 222 are arranged in the electron beam column 102.

The electron emission source 201, the illumination lens 202, the shaping aperture array substrate 203, the electromagnetic lens 205, the batch deflector 212, the limiting aperture substrate 213, the electromagnetic lens 206, the E×B separator 214 (separator), the deflectors 208 and 209, the electromagnetic lens 207, and the shield electrode plate 314 form a primary electron optics 151 (illumination optical system). In addition, the shield electrode plate 314, the electromagnetic lens 207, the E×B separator 214, the deflector 218, the deflectors 225 and 226, and the electromagnetic lens 224 form a secondary electron optics 152 (detection optical system).

The multi-detector 222 has a plurality of detection elements arranged in an array (grid).

The shield electrode plate 314 (first electrode plate) has, for example, an opening in its center through which an electron beam passes, and is arranged between the electromagnetic lens 207 serving as an objective lens and a mask substrate 101.

A stage 105 that can move at least in the X and Y directions is arranged in the inspection room 103. A mask substrate 101 (target object) to be inspected is arranged on the stage 105. Examples of the mask substrate 101 include an exposure mask substrate. A chip pattern is formed on the exposure mask substrate. The chip pattern is formed by a plurality of figure patterns. By exposing and transferring the chip pattern formed on the exposure mask substrate to the semiconductor substrate multiple times, a plurality of chip patterns (wafer dies) are formed on the semiconductor substrate. The mask substrate 101 is arranged on a stage 105 with, for example, the pattern forming surface (surface) facing upward. In addition, a mirror 216 that reflects a laser beam for laser length measurement emitted from the laser length measurement system 122 arranged outside the inspection room 103 is arranged on the stage 105.

In addition, a substrate cover electrode 318 is arranged on the mask substrate 101 so as to cover at least a part of the outer periphery of the mask substrate 101. The substrate cover electrode 318 applies a retarding potential (first potential) to the mask substrate 101 from the surface side of the mask substrate 101. The retarding potential is supplied from a retarding power supply circuit 130 to the substrate cover electrode 318.

In addition, on the stage 105, a mark 111 is arranged at the same height position as the surface of the mask substrate 101. The mark 111 is arranged above the stage 105 so as to be spaced apart from the mask substrate 101, and a figure pattern is formed on its surface. As a figure pattern, for example, a plurality of cross patterns are formed.

In addition, a counter electrode plate 316 (second electrode plate) is arranged so as to cover the gap between the mask substrate 101 and the mark 111.

The same potential as the retarding potential applied to the surface of the mask substrate 101 is applied from the retarding power supply circuit 130 to the shield electrode plate 314, the mark 111, and the counter electrode plate 316.

In addition, the multi-detector 222 is connected to the detection circuit 106 outside the electron beam column 102. The detection circuit 106 is connected to the chip pattern memory 123.

In addition, a z sensor 211 for measuring the height position of the mask substrate 101 is arranged above the inspection chamber 103. The z sensor 211 has a light projector and a position sensor that serves as a light receiver, and measures the height position of an irradiated place by making laser light from the light projector obliquely incident on the mask substrate 101 and receiving reflected light from the mask substrate 101 using the position sensor.

In the control system circuit 160, a control calculator 110 that controls the entire inspection apparatus 100 is connected to a position circuit 107, a comparison circuit 108, a reference image creation circuit 112, a stage control circuit 114, a lens control circuit 124, a blanking control circuit 126, a deflection control circuit 128, a retarding power supply circuit 130, an E×B separator control circuit 132, a storage device 109 such as a magnetic disk drive, a monitor 117, a memory 118, and a printer 119 through a bus 120. In addition, the deflection control circuit 128 is connected to DAC (digital-to-analog conversion) amplifiers 144, 146, 147, and 149 and a power supply (VPS) 148. The DAC amplifier 146 is connected to the deflector 208, and the DAC amplifier 144 is connected to the deflector 209. The power supply 148 is connected to the deflector 218. The DAC amplifier 147 is connected to the deflector 225. The DAC amplifier 149 is connected to the deflector 226.

In addition, the chip pattern memory 123 is connected to the comparison circuit 108. In addition, the stage 105 is driven by a drive mechanism 142 under the control of the stage control circuit 114. In the drive mechanism 142, for example, a drive system such as a three-axis (X-Y-θ) motor for driving in the X, Y, and θ directions in the stage coordinate system is configured, so that the stage 105 can move in the X, Y, and θ directions. As these X motor, Y motor, and θ motor (not shown), for example, step motors can be used. The stage 105 can be moved in the horizontal direction and the rotational direction by a motor of each axis of X, Y, and θ. Then, the moving position of the stage 105 is measured by the laser length measurement system 122 and supplied to the position circuit 107. The laser length measurement system 122 measures the position of the stage 105 based on the principle of the laser interferometry by receiving light reflected from the mirror 216. In the stage coordinate system, for example, X, Y, and θ directions of the primary coordinate system are set with respect to the plane perpendicular to the optical axis of multiple primary electron beams 20.

The electromagnetic lens 202, the electromagnetic lens 205, the electromagnetic lens 206, the electromagnetic lens 207, and the electromagnetic lens 224 are controlled by the lens control circuit 124. In addition, the batch deflector 212 is formed by electrodes having two or more poles, and each electrode is controlled by the blanking control circuit 126 through a DAC amplifier (not shown). The deflector 209 is formed by electrodes having four or more poles, and each electrode is controlled by the deflection control circuit 128 through the DAC amplifier 144. The deflector 208 is formed by electrodes having four or more poles, and each electrode is controlled by the deflection control circuit 128 through the DAC amplifier 146. The deflector 225 is formed by electrodes having four or more poles, and each electrode is controlled by the deflection control circuit 128 through the DAC amplifier 147. The deflector 226 is formed by electrodes having four or more poles, and each electrode is controlled by the deflection control circuit 128 through the DAC amplifier 149.

The deflector 218 (bender) is formed by, for example, a plurality of electrodes facing each other that are formed in a cylindrical shape bent in an arc shape, and the potential of each electrode is controlled by the deflection control circuit 128 through the power supply 148. Alternatively, the deflector 218 may be formed by electrodes having two or more poles, and the potential of each electrode may be controlled by the deflection control circuit 128 through the power supply 148 to improve the uniformity of the deflection electric field.

The E×B separator 214 is controlled by the E×B separator control circuit 132.

A high-voltage power supply circuit (not shown) is connected to the electron emission source 201, and a group of electrons emitted from the cathode are accelerated by the application of an acceleration voltage from the high-voltage power supply circuit between a filament and an extraction electrode (not shown) in the electron emission source 201, the application of a voltage to a predetermined extraction electrode (Wenert), and the heating of the cathode at a predetermined temperature, and emitted as electron beams 200.

Here, FIG. 1 describes components necessary for explaining Embodiment 1. The inspection apparatus 100 may also include other components that are normally required.

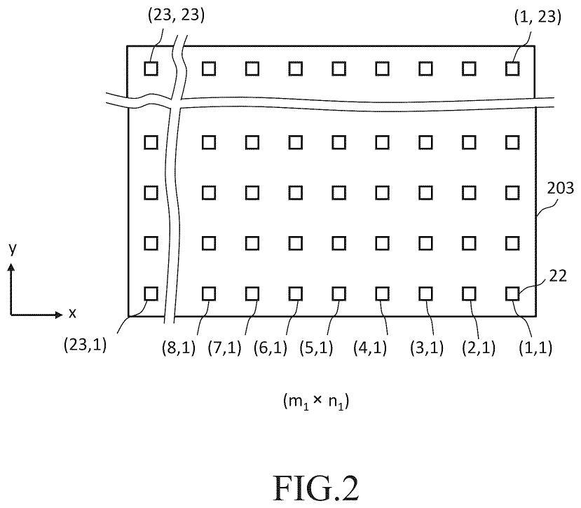

FIG. 2 is a conceptual diagram showing the configuration of a shaping aperture array substrate in Embodiment 1. In FIG. 2, on the shaping aperture array substrate 203, two-dimensional m₁ rows wide (x direction)×n₁ columns long (y direction) (m₁ and n₁ are integers of 2 or more) holes (openings) 22 are formed at predetermined arrangement pitches in the x and y directions. In the example of FIG. 2, a case where 23×23 holes (openings) 22 are formed is shown. The holes 22 are formed in rectangles having the same dimension and shape. Alternatively, the holes 22 may be circles having the same outer diameter. Some of electron beams 200 pass through the plurality of holes 22 to form multiple primary electron beams 20. The shaping aperture array substrate 203 is an example of a multi-beam forming mechanism for forming the multiple primary electron beams 20.

The image acquisition mechanism 150 acquires an image to be inspected of a figure pattern from the mask substrate 101 on which the figure pattern is formed by using multiple beams using electron beams. Hereinafter, the operation of the image acquisition mechanism 150 in the inspection apparatus 100 will be described.

The electron beam 200 emitted from the electron emission source 201 (emission source) are refracted by the electromagnetic lens 202 to illuminate the entire shaping aperture array substrate 203. As shown in FIG. 2, a plurality of holes 22 (openings) are formed in the shaping aperture array substrate 203, and the electron beam 200 illuminates a region including all of the plurality of holes 22. Some of the electron beams 200 emitted to the positions of the plurality of holes 22 pass through the plurality of holes 22 in the shaping aperture array substrate 203 to form the multiple primary electron beams 20.

The formed multiple primary electron beams 20 are refracted by the electromagnetic lens 205 and the electromagnetic lens 206, and proceed to the ExB separator 214, which is arranged at the height of the intermediate image plane (image plane conjugate position: I.I.P.) of each beam of the multiple primary electron beams 20 while repeating intermediate images and crossovers. Then, the multiple primary electron beams 20 pass through the E×B separator 214 and proceed to the electromagnetic lens 207. In addition, scattered beams can be blocked by arranging the limiting aperture substrate 213 having a limited through hole near the crossover position of the multiple primary electron beams 20. In addition, all of the multiple primary electron beams 20 can be blanked by collectively deflecting all of the multiple primary electron beams 20 with the batch deflector 212 and blocking all of the multiple primary electron beams 20 with the limiting aperture substrate 213.

When the multiple primary electron beams 20 are incident on the electromagnetic lens 207, the electromagnetic lens 207 forms an image of the multiple primary electron beams 20 on the mask substrate 101. In other words, the electromagnetic lens 207 guides multiple primary electron beams 20 (electron beams) onto the mask substrate 101. In other words, the electromagnetic lens 207 irradiates the mask substrate 101 with the multiple primary electron beams 20. In this manner, the primary electron optics 151 illuminates the mask substrate 101 with the multiple primary electron beams 20.

The multiple primary electron beams 20 focused on the surface of the mask substrate 101 (target object) by the electromagnetic lens 207, are collectively deflected by the deflectors 208 and 209, and are emitted to the irradiation position of each beam on the mask substrate 101. In this manner, the primary electron optics 151 illuminates the mask substrate 101 with the multiple primary electron beams 20.

When the multiple primary electron beams 20 are emitted to a desired position on the mask substrate 101, a group of secondary electrons (multiple secondary electron beams 300) including reflected electrons are emitted from the mask substrate 101 due to the emission of the multiple primary electron beams 20. A secondary electron beam corresponding to each of the multiple primary electron beams 20 is emitted.

The multiple secondary electron beams 300 emitted from the mask substrate 101 pass through the electromagnetic lens 207 and proceed to the E×B separator 214.

The E×B separator 214 separates the multiple secondary electron beams 300 from the trajectories of the multiple primary electron beams 20.

The E×B separator 214 has a plurality of magnetic poles (electromagnetic deflection coils) having two or more poles using coils and a plurality of electrodes (electrostatic deflection electrodes) having two or more poles. For example, two magnetic poles facing each other and two electrodes facing each other with a phase shift of 90° are arranged. The arrangement method is not limited thereto. For example, an electrode can be made to serve as a magnetic pole, and an electrode that also serves as a magnetic pole and has four or eight poles can be arranged. Since the E×B separator 214 deflects the multiple secondary electron beams 300, no separation effect occurs. The E×B separator 214 generates a directional magnetic field using a plurality of magnetic poles. Similarly, a directional electric field is generated by a plurality of electrodes. Specifically, the E×B separator 214 generates an electric field E and a magnetic field B so as to be perpendicular to each other on a plane perpendicular to a direction in which the central beam of the multiple primary electron beams 20 travels (central axis of trajectory). The electric field applies a force in the same direction regardless of the traveling direction of the electron. On the other hand, the magnetic field applies a force according to the Fleming's left-hand rule. Therefore, the direction of the force acting on the electron can be changed depending on the electron's traveling direction. In the multiple primary electron beams 20 incident on the E×B separator 214 from above, a force FE due to the electric field and a force FB due to the magnetic field cancel each other out. Therefore, the multiple primary electron beams 20 travel straight downward. On the other hand, in the multiple secondary electron beams 300 incident on the E×B separator 214 from below, both the force FE due to the electric field and the force FB due to the magnetic field act in the same direction. Therefore, the multiple secondary electron beams 300 are bent obliquely upward by being deflected in a predetermined direction, and are separated from the trajectories of the multiple primary electron beams 20.

The multiple secondary electron beams 300, which are bent obliquely upward and separated from the multiple primary electron beams 20, are guided to the multi-detector 222 by the secondary electron optics 152. Specifically, the multiple secondary electron beams 300 separated from the multiple primary electron beams 20 are further bent by being deflected by the deflector 218, and proceed to the electromagnetic lens 224. Then, the multiple secondary electron beams 300 are projected onto the multi-detector 222 while being refracted in the focusing direction by the electromagnetic lens 224 at positions away from the trajectories of the multiple primary electron beams 20. The multi-detector 222 (multiple secondary electron beam detector) detects the multiple secondary electron beams 300 separated from the trajectories of the multiple primary electron beams 20. In other words, the multi-detector 222 detect the multiple secondary electron beams 300 that have been refracted and projected. The multi-detector 222 has a plurality of detection elements (for example, diode type two-dimensional sensors (not shown)). Then, each of the multiple primary electron beams 20 collides with a detection element corresponding to each of the multiple secondary electron beams 300 on the detection surface of the multi-detector 222 to generate electrons, thereby generating secondary electron image data for each pixel. The intensity signal detected by the multi-detector 222 is output to the detection circuit 106.

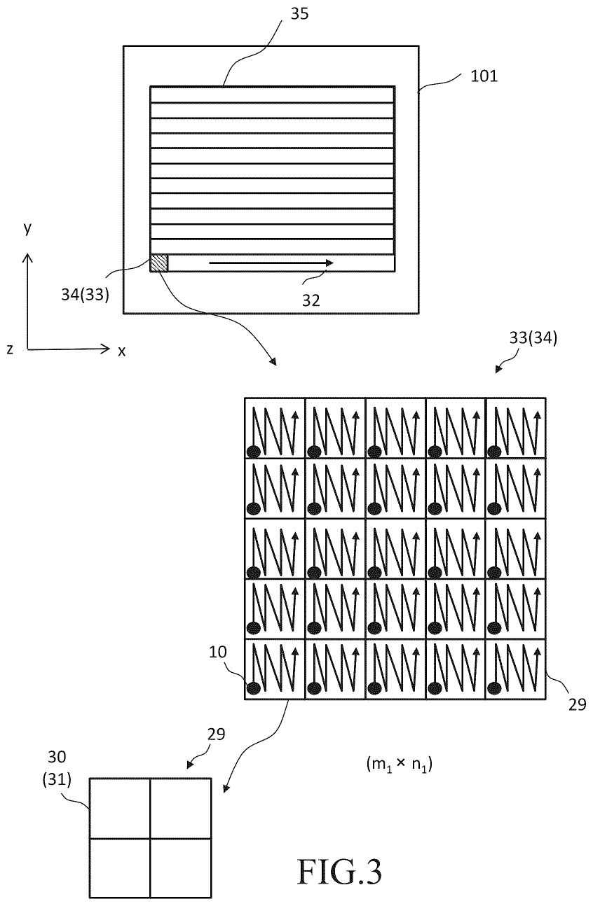

FIG. 3 is a diagram for explaining image acquisition processing in Embodiment 1. As shown in FIG. 3, an inspection region 35 where a pattern to be inspected of the mask substrate 101 is arranged is divided into a plurality of striped regions 32 with a predetermined width in the y direction, for example. In the inspection region 35, a pattern for one chip is usually formed. Therefore, the inspection region 35 is also called a pattern forming region or a chip region.

The scanning operation of the image acquisition mechanism 150 is performed, for example, for each striped region 32. For example, while moving the stage 105 in the −x direction, the scanning operation on the striped region 32 is performed relatively in the x direction. Each striped region 32 is divided into a plurality of rectangular regions 33 in the longitudinal direction. The movement of the beam to the target rectangular region 33 is performed by batch deflection of all of the multiple primary electron beams 20 by the two stages of deflectors 208 and 209 (electrostatic deflectors).

In the example of FIG. 3, for example, a case of 5×5 multiple primary electron beams 20 is shown. An irradiation region 34 that can be irradiated by one emission of the multiple primary electron beams 20 is defined by (x-direction size obtained by multiplying the x-direction beam-to-beam pitch of the multiple primary electron beams 20 on the surface of the mask substrate 101 by the number of x-direction beams)×(y-direction size obtained by multiplying the y-direction beam-to-beam pitch of the multiple primary electron beams 20 on the surface of the mask substrate 101 by the number of y-direction beams). The irradiation region 34 is a field of view of the multiple primary electron beams 20. Then, each primary electron beam 10 forming the multiple primary electron beams 20 is emitted to a sub-irradiation region 29 surrounded with the x-direction beam-to-beam pitch and the y-direction beam-to-beam pitch in which the beam itself is located, thereby scanning (scanning operation) the inside of the sub-irradiation region 29. Each primary electron beam 10 is responsible for any of the sub-irradiation regions 29 that are different from each other. Then, each primary electron beam 10 is emitted to the same position in the corresponding sub-irradiation region 29. The two stages of deflectors 208 and 209 collectively deflects the multiple primary electron beams 20 to scan the surface of the mask substrate 101 on which patterns are formed with the multiple primary electron beams 20. In other words, the movement of the primary electron beam 10 in the sub-irradiation region 29 is performed by collectively deflecting all of the multiple primary electron beams 20 using the two stages of deflectors 208 and 209. This operation is repeated to sequentially irradiate the inside of one sub-irradiation region 29 with one primary electron beam 10.

It is preferable that the width of each striped region 32 is set to a size similar to the y-direction size of the irradiation region 34 or a size reduced by the scan margin. In the example of FIG. 3, a case where the irradiation region 34 has the same size as the rectangular region 33 is shown. However, the invention is not limited thereto. The irradiation region 34 may be smaller than the rectangular region 33. Alternatively, the irradiation region 34 may be larger than the rectangular region 33. Then, each primary electron beam 10 forming the multiple primary electron beams 20 is emitted into the sub-irradiation region 29 where the beam itself is located, thereby scanning (scanning operation) the inside of the sub-irradiation region 29. Then, after the end of the scanning of one sub-irradiation region 29, the irradiation position is moved to the adjacent rectangular region 33 in the same striped region 32 by collective deflection of all of the multiple primary electron beams 20 by the two stages of deflectors 208 and 209. This operation is repeated to irradiate the inside of the striped region 32 in order. After the end of the scanning of one striped region 32, the irradiation region 34 is moved to the next striped region 32 by the movement of the stage 105 and/or collective deflection of all of the multiple primary electron beams 20 using the two stages of deflectors 208 and 209. By emitting each primary electron beam 10 as described above, the scanning operation for each sub-irradiation region 29 and the acquisition of a secondary electron image are performed. By combining the secondary electron images for the respective sub-irradiation regions 29, a secondary electron image of the rectangular region 33, a secondary electron image of the striped region 32, or a secondary electron image of the inspection region 35 is formed. In addition, when actually performing image comparison, the sub-irradiation region 29 in each rectangular region 33 is further divided into a plurality of frame regions 30, and frame images 31 that are measurement images for the respective frame regions 30 are compared. In the example of FIG. 3, a case is shown in which the sub-irradiation region 29 scanned with one primary electron beam 10 is divided into four frame regions 30 that are formed by equally dividing the sub-irradiation region 29 in the x and y directions, for example.

In addition, when the mask substrate 101 is irradiated with the multiple primary electron beams 20 while the stage 105 is continuously moving, a tracking operation by collective deflection of the two stages of deflectors 208 and 209 is performed so that the irradiation position of the multiple primary electron beams 20 follows the movement of the stage 105. Therefore, the emission positions of the multiple secondary electron beams 300 change from moment to moment with respect to the central axis of the trajectories of the multiple primary electron beams 20. Similarly, when scanning the inside of the sub-irradiation region 29, the emission position of each secondary electron beam changes from moment to moment in the sub-irradiation region 29. For example, the two stages of deflectors 225 and 226 collectively deflect the multiple secondary electron beams 300 so that each secondary electron beam whose emission position has changed is emitted into the corresponding detection region of the multi-detector 222. In other words, the two stages of deflectors 225 and 226 fix the positions of the multiple secondary electron beams 300 on the detection surface of the multi-detector 222, which change due to scanning using the multiple primary electron beams 20, by back deflection of the multiple secondary electron beams. In this manner, each secondary electron beam can be detected by a corresponding detection element of the multi-detector 222. In addition, the deflectors 225 and 226 are not limited to two stages of deflectors, and may be configured as a single-stage deflector.

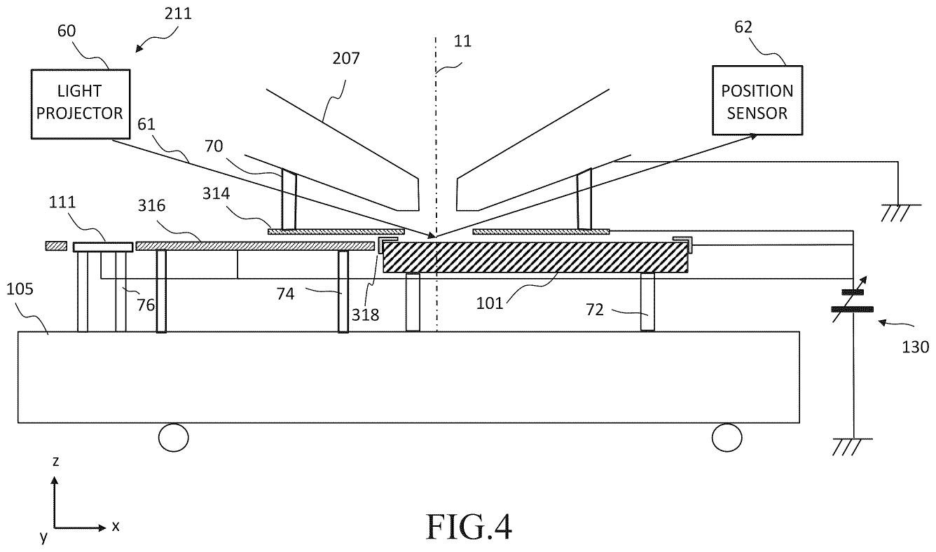

FIG. 4 is a diagram showing an example of the configuration of the vicinity of arrangement positions of a substrate and a mark in Embodiment 1. In FIG. 4, the mask substrate 101 is supported above the stage 105 by a plurality of support pins 72 at, for example, three points. In addition, the mark 111 is arranged at a position spaced apart from the mask substrate 101 above the stage 105 so that its surface is at the same height position as the surface of the mask substrate 101. The mark 111 is supported above the stage 105 by a plurality of support pillars 76. The pole piece of the electromagnetic lens 207 arranged under the electron optical column 102 is grounded and controlled to have a ground potential. Therefore, the lower surface of the pole piece, in other words, the surface of the electromagnetic lens 207 facing the mask substrate 101, is controlled to have a ground potential (second potential) different from the retarding potential (first potential).

Here, as described above, in image acquisition using an electron beam, there is an optimum landing energy of the electron beam depending on the yield of the mask substrate to be inspected. For this reason, for example, a negative retarding potential is applied to the mask substrate 101 through the substrate cover electrode 318. On the other hand, the lower surface of the electron optical column 102 is controlled to have a ground potential. In the example of FIG. 1, for example, the lower surface of the electromagnetic lens 207 serving as an objective lens becomes the lower surface of the electron optical column 102. The lower surface of the electromagnetic lens 207 is grounded and controlled to have a ground potential. The trajectory of the electron beam is aligned by alignment coils which are not shown in FIG. 4 for an electron optics central axis 11. The electron beam travels along the electron optics central axis 11 after aligned.

When a retarding potential is applied to the mask substrate 101, a potential difference occurs between the mask substrate 101 and the lower surface of the electromagnetic lens 207, generating an electric field. On the other hand, the retarding potential is applied to the outer periphery of the mask substrate 101 from the surface side of the mask substrate 101 by the substrate cover electrode 318. For this reason, a structure for applying a retarding potential to the surface of the mask substrate 101 is arranged on the mask substrate 101. This has caused a problem that the electric field is disturbed to change the trajectory of the electron beam and reduce the inspection accuracy. Therefore, in Embodiment 1, for example, the shield electrode plate 314 is arranged axially symmetrically with respect to the electron optics central axis 11 of the multiple primary electron beams 20. For example, a disk-shaped shield electrode plate 314 is arranged. An opening through which the multiple primary electron beams 20 can pass is formed in the center of the shield electrode plate 314. The opening is formed, for example, in a circular shape having a predetermined radius. By arranging the shield electrode plate 314, it is possible to eliminate the undesired electric field which generated by the substrate cover electrode 318 so as not to be exposed when the mask substrate 101 is irradiated with the multiple primary electron beams 20. Then, the same potential as the retarding potential applied to the mask substrate 101 is applied from the retarding power supply circuit 130 to the shield electrode plate 314. Therefore, the shield electrode plate 314 and the mask substrate 101 have the same potential, so that it is possible to prevent an electric field from being generated between the shield electrode plate 314 and the mask substrate 101. As a result, it is possible to suppress or reduce disturbances in the electric field due to structures such as the substrate cover electrode 318.

The closer the shield electrode plate 314 is to the mask substrate 101, the better. Therefore, the shield electrode plate 314 is arranged at a height position close to the mask substrate 101 so as not to come into contact with the substrate cover electrode 318. It is preferable to set the gap between the shield electrode plate 314 and the substrate cover electrode 318 to 1 mm or less, for example.

In Embodiment 1, the z sensor 211 (height position measurement sensor) for measuring the surface height position of the mask substrate 101 is arranged. Specifically, a light projector 60 of the z sensor 211 makes laser light 61 obliquely incident on the mask substrate 101 through the opening of the shield electrode plate 314 from between the electromagnetic lens 207 serving as an objective lens and the shield electrode plate 314. Then, a position sensor 62 of the z sensor 211 receives reflected light 63 from the mask substrate 101, the reflected light 63, reflected by the surface of the mask substrate 101 due to the laser light 61 obliquely incident on the mask substrate 101, traveling between the electromagnetic lens 207 and the shield electrode plate 314 through the opening of the shield electrode plate 314, thereby measuring the surface height of the mask substrate 101. In Embodiment 1, since the laser light is obliquely incident between the electromagnetic lens 207 and the shield electrode plate 314, the distance between the shield electrode plate 314 and the mask substrate 101 can be made smaller than when the laser light is obliquely incident between the shield electrode plate 314 and the mask substrate 101. Therefore, the potential shielding effect of the shield electrode plate 314 can be improved.

The inspection apparatus 100 requires calibration of the multiple primary electron beams 20. This calibration operation is performed, for example, multiple times while an image of one substrate is being acquired. The calibration operation is performed by scanning the mark 111 arranged at a position separate from the mask substrate 101 with the multiple primary electron beams 20. For example, the focal position is calibrated. Secondary electrons emitted from the mark 111 when the mark 111 is scanned with the multiple primary electron beams 20 are detected by the multi-detector 222 or a detector (not shown) arranged above the electromagnetic lens 207. Then, the focal position is adjusted by the electromagnetic lens 207 to a position where the obtained secondary electron image becomes as clear as possible.

The same potential as the retarding potential applied to the mask substrate 101 is applied from the retarding power supply circuit 130 to the mark 111. It is preferable that the mark 111 is formed of, for example, silicon (Si) material, and its surface is covered with a conductor such as metal, for example, platinum palladium. For example, the same potential as the retarding potential is applied to the mark 111 from the back surface side. During the calibration operation, the stage 105 is moved to a position where the mark 111 can be irradiated with the multiple primary electron beams 20. In other words, the central axis 11 of the electron optics is moved relatively on the mark 111. Therefore, during beam irradiation, the outer periphery of the mark 111 is covered by the shield electrode plate 314. As a result, the energy conditions of the mark 111 and the mask substrate 101 can be the same during beam irradiation.

Here, as described above, providing the shield electrode plate 314 having the same potential as the retarding voltage causes another problem. When the stage 105 is moved to a position where the mark 111 is within the emission range of the multiple primary electron beams 20, there is a problem in that discharge may occur between the shield electrode plate 314 and the stage 105 or between the shield electrode plate 314 and a structure on the stage 105. Therefore, in Embodiment 1, as shown in FIG. 4, the counter electrode plate 316 (second electrode plate) is arranged on the stage 105 so as to cover the gap between the mask substrate 101 and the mark 111. Specifically, the counter electrode plate 316 is arranged so as to cover the upper surface of the stage 105 between the mask substrate 101 and the mark 111 or a structure on the stage 105. The counter electrode plate 316 is arranged at a height position lower than that of the shield electrode plate 314 and equal to or higher than the height position of the surface of the mask substrate 101. The same potential as the retarding potential applied to the mask substrate 101 is applied from the retarding power supply circuit 130 to the counter electrode plate 316. For example, the same potential as the retarding potential is applied to the counter electrode plate 316 from the back surface side. The counter electrode plate 316 is supported above the stage 105 by a plurality of support pillars 74. When the stage 105 is moved, the counter electrode plate 316 moves relatively directly below the shield electrode plate 314. Since the counter electrode plate 316 and the shield electrode plate 314 are controlled to have the same potential, it is possible to suppress discharge when the stage 105 is moved.

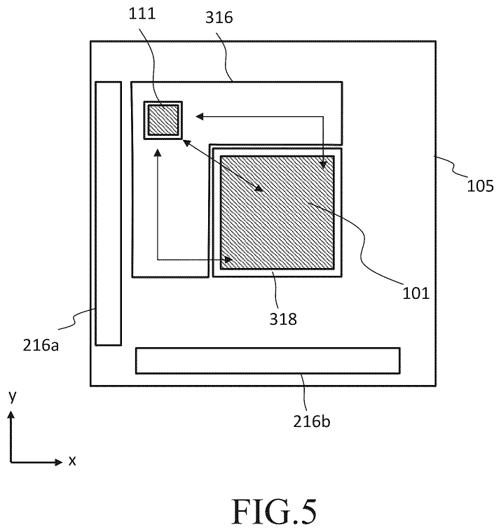

FIG. 5 is a diagram showing an example of a moving path of the central axis of the electron optics on the stage in Embodiment 1. The mark 111 is preferably arranged, for example, on the side of a reflecting mirror 216 for laser interference when viewed from the mask substrate 101. In the example of FIG. 5, a case where the mark 111 is arranged on the extensions of the diagonal lines of the four corners of the mask substrate 101 is shown as an example. The counter electrode plate 316 is formed, for example, in an L shape when viewed from above so as to surround the periphery of the mark 111 and to be along two entire sides on the mark 111 side among the four sides of the mask substrate 101. By using such a shape, even if the central axis of the electron optics moves from any position on the mask substrate 101 onto the mark 111, the entire path (arrow) from the mask substrate 101 to the mark 111 can be contained within the counter electrode plate 316.

The gap between the substrate cover electrode 318 and the counter electrode plate 316 and the gap between the mark 111 and the counter electrode plate 316 are preferably narrow. For example, it is preferable to set the gap between the substrate cover electrode 318 and the counter electrode plate 316 and the gap between the mark 111 and the counter electrode plate 316 to 1 mm or less.

In the examples of FIGS. 4 and 5, a case is shown in which the mark 111 and the counter electrode plate 316 are formed separately. However, the invention is not limited thereto. The mark 111 may be formed on a part of the counter electrode plate 316. In other words, the mark 111 and the counter electrode plate 316 may be integrally formed.

In addition, although a case where the same potential is applied from the same power supply in the retarding power supply circuit 130 to the substrate cover electrode 318, the shield electrode plate 314, the mark 111, and the counter electrode plate 316 is shown in the example of FIG. 4, the invention is not limited thereto.

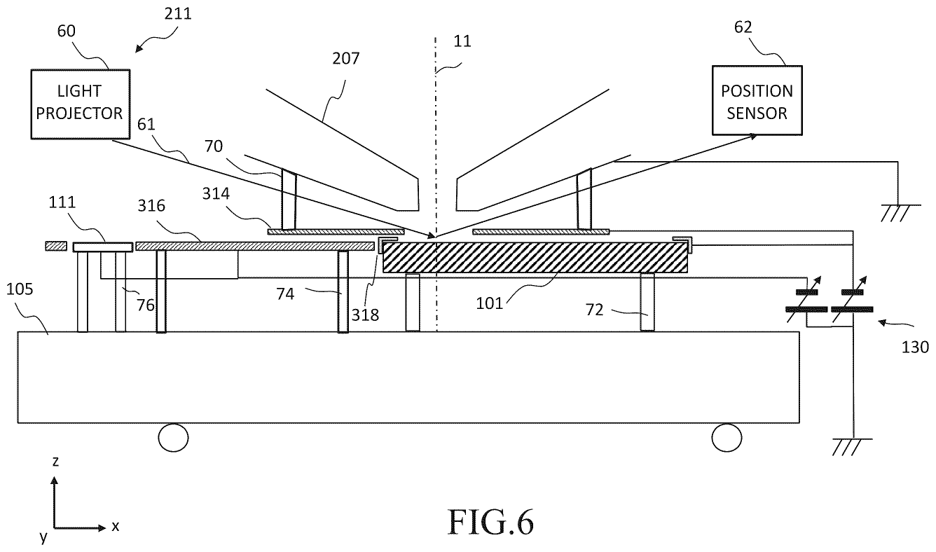

FIG. 6 is a diagram showing another example of the configuration of the vicinity of arrangement positions of a substrate and a mark in Embodiment 1. In the example of FIG. 6, a case is shown in which a power supply for applying the retarding potential to the substrate cover electrode 318 and the shield electrode plate 314 and a power supply for applying the same potential as the retarding potential to the mark 111 and the counter electrode plate 316 are separated. In this manner, by using separate power supplies, potential errors due to wiring impedance and the like can be corrected. In the example of FIG. 6, a case of dividing into a group of the substrate cover electrode 318 and the shield electrode plate 314 and a group of the mark 111 and the counter electrode plate 316 is shown, but the invention is not limited thereto. The substrate cover electrode 318, the shield electrode plate 314, the mark 111, and the counter electrode plate 316 may be divided into a group including one of these components and a group including the remaining three components and a potential may be applied from two power supplies, or may be divided into a group including two of these components and a group including the remaining two components and a potential may be applied from two power supplies. Alternatively, the substrate cover electrode 318, the shield electrode plate 314, the mark 111, and the counter electrode plate 316 may be divided into a group including one of these components, a group including another one of these components, and a group including the remaining two components and a potential may be applied from three power supplies. Alternatively, a potential may be applied from separate power supplies to the substrate cover electrode 318, the shield electrode plate 314, the mark 111, and the counter electrode plate 316.

In addition, as shown in FIGS. 4 and 6, the shield electrode plate 314 is supported by a plurality of support pillars 70 extending from a member that is controlled to have a ground potential and is located above the shield electrode plate 314. In addition, it is preferable that the shield electrode plate 314 is supported by a plurality of support pillars 70 extending from a member fixed to the electron optical column 102. Even if the inspection chamber 103 is deformed, the positional relationship between the electromagnetic lens 207 serving as an objective lens and the shield electrode plate 314 can be maintained with high accuracy. The plurality of support pillars 70 are formed of an insulating material. For example, it is preferable that the plurality of support pillars 70 are formed of aluminum oxide ceramics. The electromagnetic lens 207 is an example of a member that is controlled to have a ground potential. In addition, the electromagnetic lens 207 is an example of a member fixed to the electron optical column 102. In the examples of FIGS. 4 and 6, cases are shown in which the shield electrode plate 314 is supported by a plurality of support pillars 70 extending from the lower surface of the electromagnetic lens 207.

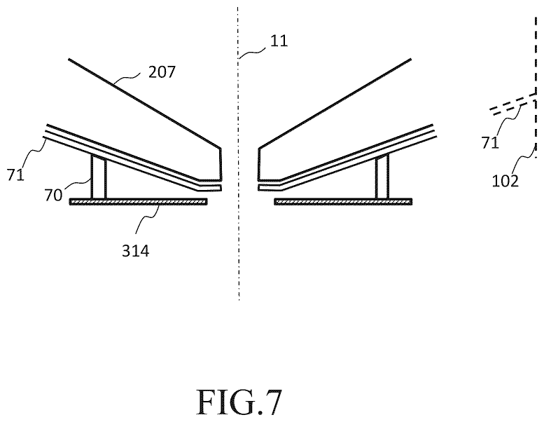

FIG. 7 is a diagram showing another example of the configuration of the vicinity of arrangement positions of a substrate and a mark in Embodiment 1. A heat shield 71 may be arranged on the lower surface side of the electromagnetic lens 207 serving as an objective lens. The heat shield 71 is another example of a member controlled to have a ground potential. In addition, the heat shield 71 is another example of a member fixed to the electron optical column 102. In the example of FIG. 7, a case is shown in which the shield electrode plate 314 is supported by a plurality of support pillars 70 extending from the lower surface of the heat shield 71.

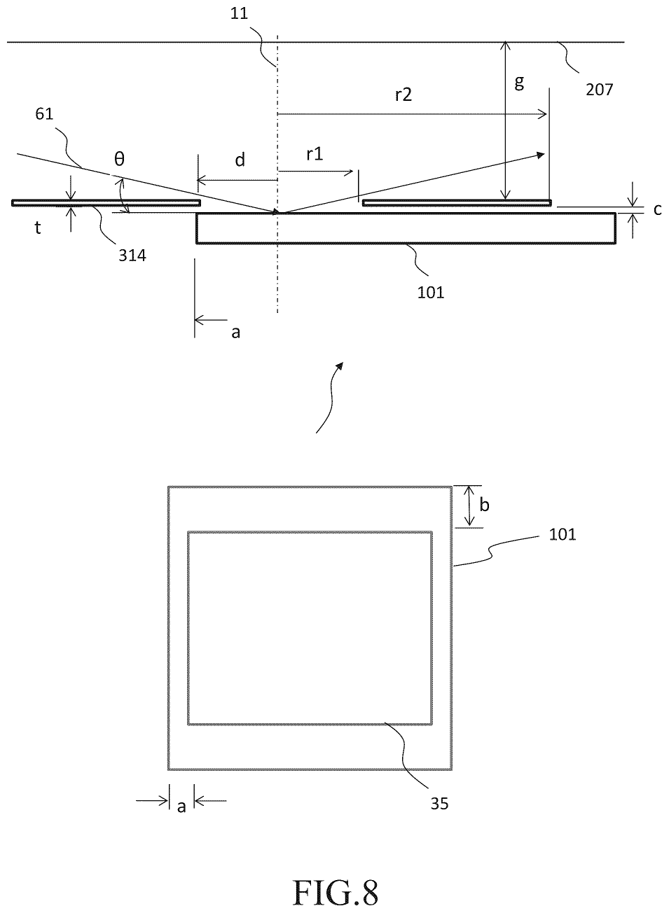

FIG. 8 is a diagram for explaining the size of the shield electrode plate in Embodiment 1. An inspection region 35 in the square mask substrate 101 is formed in a rectangular shape, as shown in the lower diagram of FIG. 8. Therefore, the distance a from one of the two opposite sides of the four sides at the outer peripheral edge of the mask substrate 101 to the edge of the inspection region 35 is different from the distance b from the other opposite two sides to the edge of the inspection region 35. In the example of FIG. 8, a case is shown in which the distance a is shorter than the distance b.

The inner radius r1 (radius of the opening) of the shield electrode plate 314 in which a circular opening is formed may satisfy the relational expression of the following Expression (1) using a distance d from the electron optical central axis 11 of the multiple primary electron beams 20 (electron beam) to a position where the incident trajectory of the laser light of the z sensor 211 crosses a plane perpendicular to the electron optics central axis 11 at the surface height position of the shield electrode plate 314 and the shorter distance a from the edge of the mask substrate 101 to the inspection region 35. In addition, the opening is formed axially symmetrically with respect to the electron optics central axis 11. In this manner, the shield electrode plate 314 can cover the edge of the mask substrate 101 and prevent interference with the laser light of the z sensor 211.

$$d < r 1 < a \qquad ( 1 )$$

In addition, an angle θ between the incident trajectory of the laser light 61 of the z sensor 211 and the surface of the mask substrate 101 may satisfy the relational expression of the following Expression (2) using the shorter distance a from the edge of the mask substrate 101 to the inspection region 35, the thickness t of the shield electrode plate 314, and a gap c between the shield electrode plate 314 and the surface of the mask substrate 101. In this manner, the laser light of the z sensor 211 can be prevented from interfering with the shield electrode plate 314.

$$arctan \{ ( t + c ) / a \} < θ \qquad ( 2 )$$

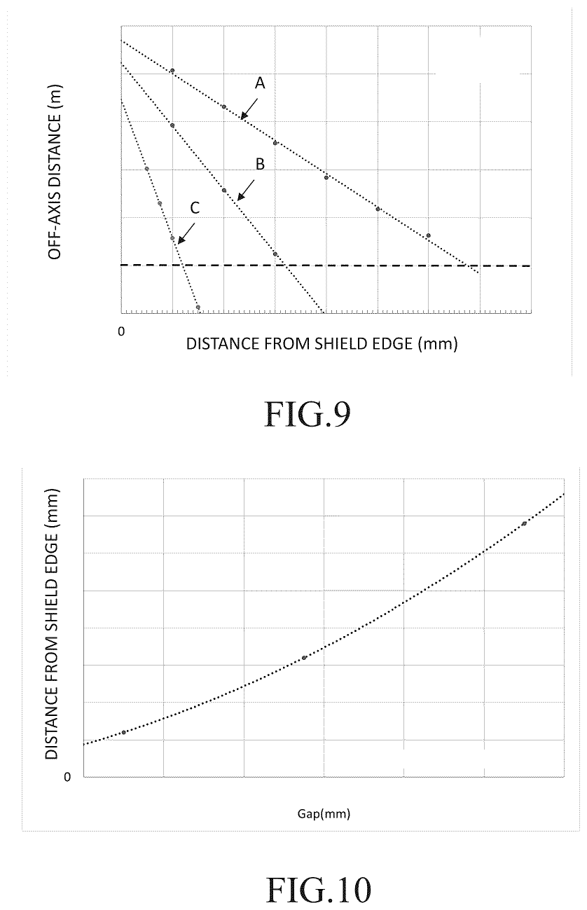

FIG. 9 is a diagram showing an example of the relationship between the off-axis distance and the distance from the outer peripheral edge of the shield electrode plate to the central axis of the electron optics in Embodiment 1. As described above, when the electric field is disturbed, the beam irradiation position deviates from the design value due to this disturbance. The off-axis distance described above corresponds to the beam position deviation. By arranging the shield electrode plate 314, the off-axis distance can be reduced. FIG. 9 shows the results of each case where a distance (gap) g between the shield electrode plate 314 and the lower surface of the nearest member (for example, the electromagnetic lens 207) having a ground potential that forms an electric field is variable. The results are shown in order of A, B, and C from the largest distance g. It can be seen that the smaller the distance g, the smaller the distance from the outer peripheral edge of the shield electrode plate 314 to the central axis 11 of the electron optics can be made. Therefore, the outer radius r2 of the shield electrode plate 314 can be made small. In other words, the outer radius r2 of the shield electrode plate 314 depends on the distance g. The dotted line in FIG. 9 indicates a tolerance of the off-axis distance.

FIG. 10 is a diagram showing an example of the relationship between the distance r2 from the outer peripheral edge of the shield electrode plate to the central axis of the electron optics at a desired off-axis distance and the distance (gap) g between the shield electrode plate and the lower surface of the nearest member (for example, the electromagnetic lens 207) having a ground potential in Embodiment 1. The relationship between the measured distance r2 from the outer peripheral edge of the shield electrode plate 314 to the central axis 11 of the electron optics and the measured distance (gap) g from the lower surface of the nearest member (for example, the electromagnetic lens 207) having a ground potential is fitted with a polynomial. In the example of FIG. 10, this can be defined by a quadratic function.

Therefore, in order to keep the inter-axis distance within a desired range, the outer radius r2 of the shield electrode plate 314 may satisfy the relational expression of the following Expression (3) using the distance g to the nearest member (for example, the electromagnetic lens 207) having a ground potential on the shield electrode plate 314 and coefficients b1, b2, and b3.

$$b 1 {g}^{2} + b 2 g + b 3 < r 2 \qquad ( 3 )$$

For example, when the retarding potential is −30 kV and the off-axis distance is 1 nm, Expression (3) can be defined by the following Expression (4) under the condition that the gap c between the shield electrode plate 314 and the surface of the mask substrate 101 is kept constant.

$$0.21 {g}^{2} + 1.4 g - 0.24 < r 2 \qquad ( 4 )$$

In addition, when the shorter distance a from the edge of the substrate 101 to the inspection region 35 is 10 mm that is used in the normal mask substrate 101, the off-axis distance conventionally exceeded a desired tolerance (for example, 1 nm) in the absence of the shield electrode plate 314. On the other hand, it was confirmed that by arranging the shield electrode plate 314 in Embodiment 1, the off-axis distance could be kept within the tolerance at a position 10 mm or more inward from the edge of the mask substrate 101. The off-axis distance indicates the amount of deviation of the beam irradiation position from the design value. Therefore, even if the substrate surface is exposed directly above the position where the multiple primary electron beams 20 actually strike due to the opening of the shield electrode plate 314, changes in the beam trajectory due to disturbances in the electric field can be suppressed.

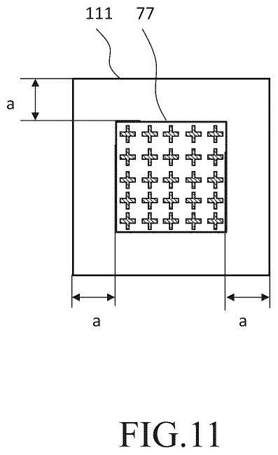

FIG. 11 is a diagram showing an example of the upper surface of a mark in Embodiment 1. In FIG. 11, the mark 111 is formed so that the distance from the counter electrode plate 316 to a mark pattern forming region 77 where a figure pattern of the mark 111 is formed is equal to or greater than the distance from the edge of the mask substrate 101 to the inspection region 35 (region to be inspected) of the mask substrate 101. Here, it is preferable that the distance from the counter electrode plate 316 to the mark pattern forming region 77 where the figure pattern of the mark 111 is formed is equal to or greater than the shorter distance a between the distances a and b. In other words, it is preferable to arrange a pattern-free region around the mark pattern forming region 77 where the figure pattern is formed. In this manner, the conditions for irradiating the mark 111 with the beam can be made to match the conditions for irradiating the mask substrate 101 with the beam. In the mark pattern forming region 77 of the mark 111, a plurality of cross patterns are arranged. For example, a plurality of cross patterns are arranged at the same number and pitch as the number and pitch of multiple primary electron beams 20 in accordance with the irradiation positions of the multiple primary electron beams 20 on the mask substrate 101. In this manner, calibration of each beam of the multiple primary electron beams 20 can be performed simultaneously.

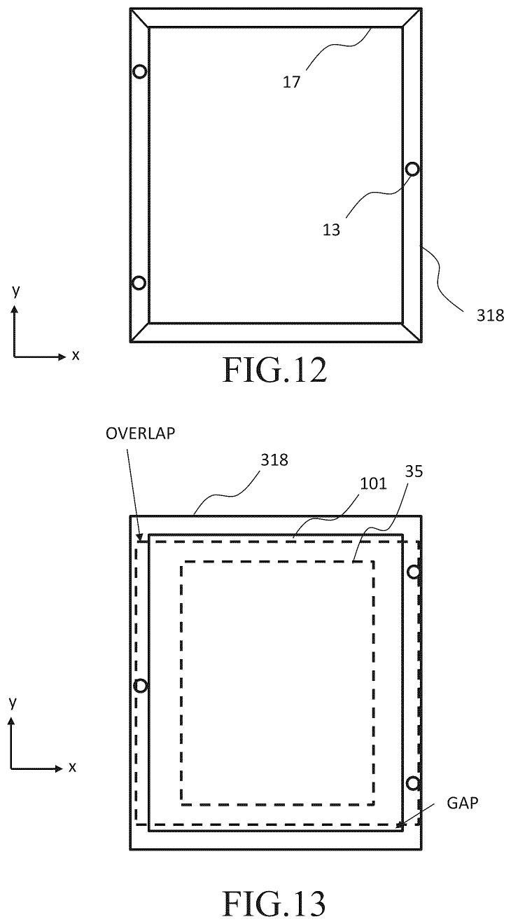

FIG. 12 is a top view showing an example of a substrate cover electrode in Embodiment 1. In FIG. 12, the substrate cover electrode 318 has a frame 17 and a plurality of conductive pins 13. The frame 17 and the plurality of conductive pins 13 are formed of a conductive material. Alternatively, a film formed of a conductive material is coated on the surface. The frame 17 is formed in a rectangular shape. Specifically, the outer periphery of the frame 17 is formed in a rectangular shape when viewed from above. Similarly, the inner periphery of the frame 17 is formed in a rectangular shape when viewed from above. The plurality of conductive pins 13 are arranged on the back surface side of the frame 17. In addition, the plurality of conductive pins 13 are arranged on the long side of the frame 17. In the example of FIG. 12, a case is shown in which two conductive pins 13 are arranged on one of the two opposite long sides and one conductive pin 13 is arranged on the other.

FIG. 13 is a diagram showing an example of a state in which a substrate cover electrode is arranged on a substrate in Embodiment 1. A plurality of conductive pins 13 are in contact with the mask substrate 101. The plurality of conductive pins 13 penetrate an insulating film such as an oxide film of the mask substrate 101 and reach a conductive film. Then, a retarding potential applied to the substrate cover electrode 318 through the plurality of conductive pins 13 is applied to the mask substrate 101. In Embodiment 1, the frame 17 is further arranged on the mask substrate 101 so as not to overlap the mask substrate 101 on the short side of the inspection region 35 and so as to partially overlap the outer periphery of the mask substrate 101 on the long side of the inspection region 35. Therefore, on the side of the mask substrate 101 that is not in contact with the conductive pins 13, the frame 17 can be arranged so as not to overlap the mask substrate 101.

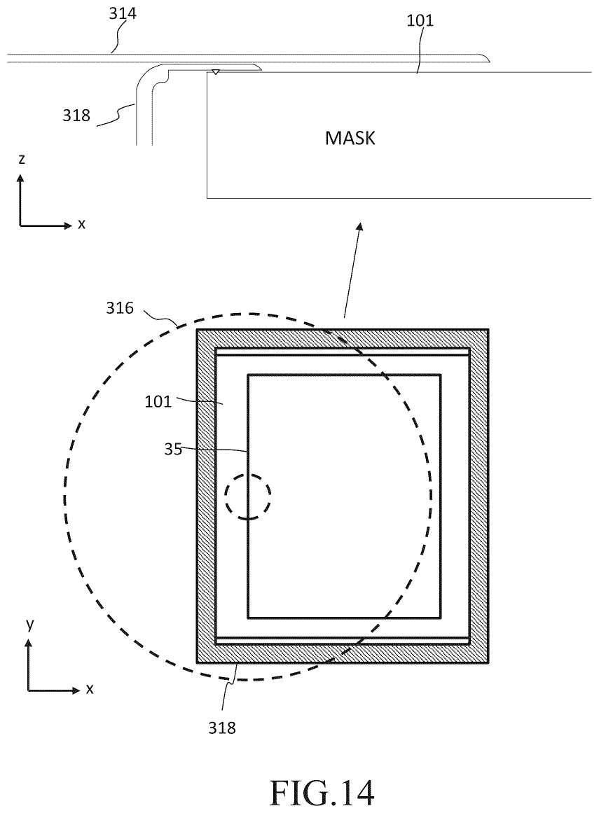

FIG. 14 is a cross-sectional view showing an example of a state in which the substrate cover electrode is arranged on the substrate on the long side of the inspection region in Embodiment 1. On the long side of the inspection region 35, the distance b from the outer peripheral edge of the mask substrate 101 to the edge of the inspection region 35 is greater than the distance a on the short side of the inspection region 35. Then, on the long side of the inspection region 35, as shown in FIG. 14, the frame 17 of the substrate cover electrode 318 overlaps the outer periphery of the mask substrate 101, and the substrate cover electrode 318 and the mask substrate 101 are electrically connected to each other by the conductive pin 13. Therefore, at this position, the frame 17 needs to be arranged above the surface height position of the mask substrate 101.

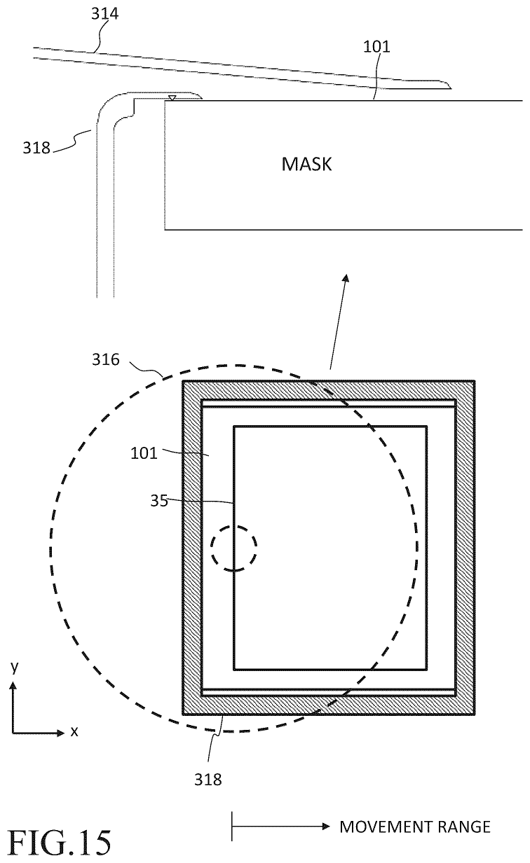

FIG. 15 is a cross-sectional view showing another example of a state in which the substrate cover electrode is arranged on the substrate on the long side of the inspection region in Embodiment 1. In the example of FIG. 15, a case is shown in which the central surface of the shield electrode plate 314 is formed horizontally and the surface of the outer periphery is formed so as to be inclined obliquely upward. By adopting such a shape, the gap c between the shield electrode plate 314 and the mask substrate 101 can be made small. However, in the example of FIG. 15, if the shield electrode plate 314 approaches the substrate cover electrode 318 further, there is a possibility that the shield electrode plate 314 and the substrate cover electrode 318 may come into contact with each other. For this reason, in the case of such a shape, it is necessary to limit the movement range of the stage 105. For example, the movement range of the stage 105 is limited so that the central axis of beam trajectory does not move relatively outside the edge of the inspection region 35 in the x direction.

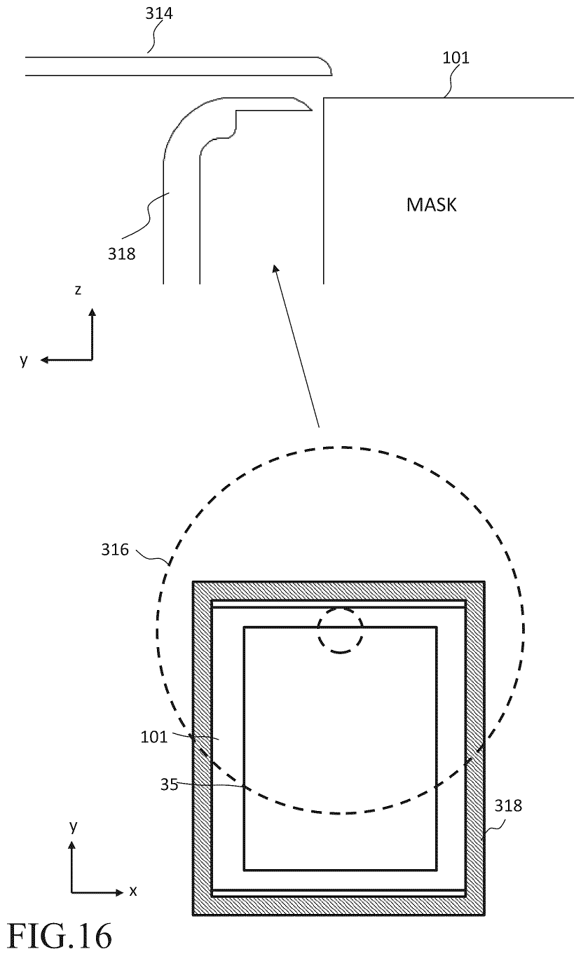

FIG. 16 is a cross-sectional view showing an example of a state in which the substrate cover electrode is arranged on the substrate on the short side of the inspection region in Embodiment 1. On the short side of the inspection region 35, the distance a from the outer peripheral edge of the mask substrate 101 to the edge of the inspection region 35 is smaller than the distance b on the long side of the inspection region 35. In addition, since the conductive pin 13 is not arranged on the short side of the frame 17 arranged on the short side of the inspection region 35, the frame 17 of the substrate cover electrode 318 can be arranged with a gap so as not to overlap the outer periphery of the mask substrate 101, as shown in FIG. 15. Therefore, at this position, the frame 17 does not need to be arranged above the surface height position of the mask substrate 101. Therefore, in Embodiment 1, it is preferable that the surface height position of the frame 17 on the long side of the substrate cover electrode 318 is higher than the surface height of the mask substrate 101 and the surface height position of the frame 17 on the short side of the substrate cover electrode 318 is lower on the surface height side of the mask substrate 101 than the height position of the frame on the long side. Specifically, the substrate cover electrode 318 is formed so that the surface height position on the short side of the frame 17 is the same height position as the surface of the mask substrate 101, for example. Therefore, in the y direction, even if the shield electrode plate 314 approaches the substrate cover electrode 318 further, it is possible to avoid contact between the shield electrode plate 314 and the substrate cover electrode 318. The same is true even when the central surface of the shield electrode plate 314 is formed horizontally and the peripheral surface is formed so as to be inclined obliquely upward or when the entire shield electrode plate 314 is horizontal. For this reason, it is not necessary to limit the movement range of the stage 105 in the y direction.

In the configuration having the arrangement described above, an image acquisition mechanism 150 acquires an image of the mask substrate 101 with the multiple primary electron beams 20.

In the scanning step (image acquisition step), the image acquisition mechanism 150 scans the mask substrate 101 with the multiple primary electron beams 20. Here, the image acquisition mechanism 150 scans each striped region 32 with the multiple primary electron beams 20. As described above, the primary electron optics 151 irradiates the mask substrate 101 with the multiple primary electron beams 20. The multiple secondary electron beams 300 emitted due to irradiating the mask substrate 101 with the multiple primary electron beams 20 are guided to the multi-detector 222 by the secondary electron optics 152. Then, the guided multiple secondary electron beams 300 are detected by the multi-detector 222. The detected multiple secondary electron beams 300 may include reflected electrons. Alternatively, the reflected electrons may diverge while moving through the secondary electron optics and may not reach the multi-detector 222. Then, a secondary electron image based on the signal of the detected multiple secondary electron beams 300 is acquired. Specifically, detection data of the secondary electrons (measurement image data, secondary electron image data, or inspected image data) for each pixel in each sub-irradiation region 29 detected by the multi-detector 222 is output to the detection circuit 106 in the order of measurement. In the detection circuit 106, analog detection data is converted into digital data by an A/D converter (not shown) and stored in the chip pattern memory 123. Then, the obtained measurement image data is transmitted to the comparison circuit 108 together with information indicating each position from the position circuit 107.

In addition, for example, every time a scanning operation on several striped regions 32 is completed, the above-described calibration is performed before starting scanning of the next striped region 32. In Embodiment 1, since the path taken to move to the mark 111 is covered by the counter electrode plate 316, discharge can be avoided or suppressed.

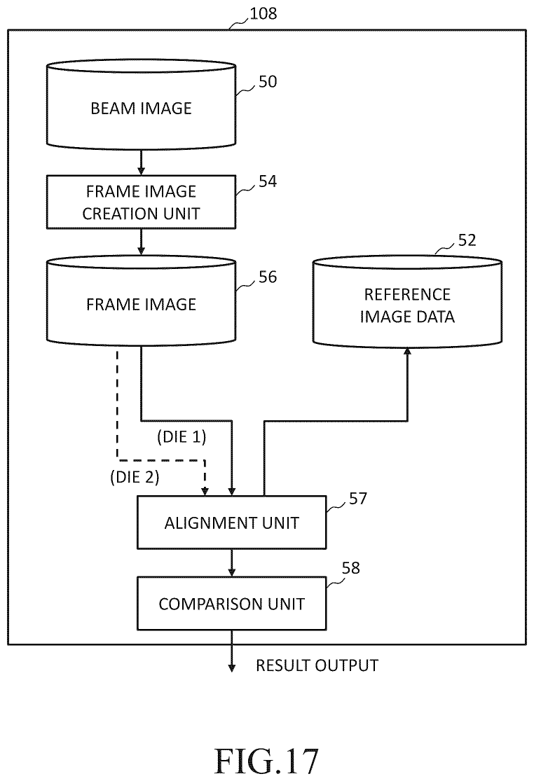

FIG. 17 is a configuration diagram showing an example of the internal configuration of a comparison circuit in Embodiment 1. In FIG. 17, storage devices 50, 52, and 56 such as magnetic disk drives, a frame image creation unit 54, an alignment unit 57, and a comparison unit 58 are arranged in the comparison circuit 108. Each “˜ unit”, such as the frame image creation unit 54, the alignment unit 57, and the comparison unit 58 includes a processing circuit, and examples of the processing circuit include an electrical circuit, a computer, a processor, a circuit board, a quantum circuit, or a semiconductor device. In addition, for each “˜ unit”, a common processing circuit (the same processing circuit) may be used. Alternatively, different processing circuits (separate processing circuits) may be used. Input data or calculation results required for the frame image creation unit 54, the alignment unit 57, and the comparison unit 58 are stored in a memory (not shown) or in the memory 118 each time.

In the comparison step, a comparison circuit 108 compares the acquired secondary electron image with a predetermined reference image. Specifically, for example, the operation is as follows.

The measurement image data (beam image) transmitted to the comparison circuit 108 is stored in the storage device 50.

Then, the frame image creation unit 54 creates a frame image 31 for each of a plurality of frame regions 30 obtained by further dividing the image data of the sub-irradiation region 29 acquired by the scanning operation of each primary electron beam. Then, the frame region 30 is used as a unit region of the image to be inspected. In addition, each frame region 30 is preferably configured such that the margin regions overlap each other so that no image is missing. The created frame image 31 is stored in the storage device 56.

On the other hand, the reference image creation circuit 112 creates a reference image corresponding to the frame image 31, for each frame region 30, based on design data that is the basis of a plurality of figure patterns formed on the mask substrate 101. Specifically, the operation is as follows. First, design pattern data is read out from the storage device 109 through the control calculator 110, and each figure pattern defined in the read design pattern data is converted into binary or multi-valued image data.

As described above, the figures defined in the design pattern data include, for example, a basic figure of a rectangle or a triangle. For example, figure data is stored in which the shape, size, position, and the like of each figure are defined by information such as the coordinates (x, y) at the reference position of the figure, the length of the side, and a figure code that serves as an identifier for identifying the figure type such as a rectangle or a triangle.

When the design pattern data that serves as the figure data is input to the reference image creation circuit 112, the design pattern data is expanded to data for each figure, and the figure code, the figure dimension, and the like indicating the figure shape of the figure data are analyzed. Then, this is expanded into binary or multi-valued design pattern image data as a pattern arranged in a square having a grid with a predetermined quantization dimension as a unit, and is output. In other words, the design data is read, the occupancy rate of the figure in the design pattern is calculated for each square created by virtually dividing the inspection region into squares each having a predetermined dimension as a unit, and n-bit occupancy rate data is output. For example, it is preferable to set one square as one pixel. Then, assuming that one pixel has a resolution of 1/2⁸(=1/256), a small region of 1/256 is allocated to the region of the figure arranged in the pixel and the occupancy rate in the pixel is calculated. Then, 8-bit occupancy rate data is obtained. Such a square (inspection pixel) may be matched with each pixel of the measurement data.

Then, the reference image creation circuit 112 performs filtering processing on the design image data of the design pattern, which is the image data of the figure, by using a predetermined filter function. In this manner, the design image data whose image intensity (shade value) is image data on the design side of the digital value can be matched with image generation characteristics obtained by emission of the multiple primary electron beams 20. The image data for each pixel of the created reference image is output to the comparison circuit 108. The reference image data transmitted to the comparison circuit 108 is stored in the storage device 52.

Then, the alignment unit 57 reads out the frame image 31 to be inspected and the reference image corresponding to the frame image 31, and aligns both the images in units of sub-pixels smaller than pixels. For example, the alignment may be performed using the least squares method.

Then, the comparison unit 58 compares the secondary electron image of the mask substrate 101 placed on the stage 105 with a predetermined image. Specifically, the comparison unit 58 compares the frame image 31 with the reference image for each pixel. The comparison unit 58 compares the frame image 31 with the reference image for each pixel according to predetermined determination conditions. For example, the comparison unit 58 determines whether or not there is a defect, such as a shape defect. For example, if the gradation value difference for each pixel is larger than a determination threshold value Th, it is determined that there is a defect. Then, the comparison result is output. The comparison result may be output to the storage device 109 or the memory 118, or may be output through the printer 119.

In addition to the die-to-database inspection described above, it is also preferable to perform a die-to-die inspection in which pieces of measurement image data obtained by imaging the same pattern at different locations on the same substrate are compared with each other. Alternatively, the inspection may be performed using only the self-measured image.

The above-described operations are repeated for all of the striped regions 32.

As described above, according to Embodiment 1, it is possible to reduce disturbances in the electric field at the outer periphery of the mask substrate 101 and to suppress discharge during beam calibration.

In the above description, the series of “˜ circuits” include a processing circuit, and examples of the processing circuit include an electrical circuit, a computer, a processor, a circuit board, a quantum circuit, or a semiconductor device. In addition, a common processing circuit (same processing circuit) may be used for the respective “˜ circuits”. Alternatively, different processing circuits (separate processing circuits) may be used. A program for executing the processor and the like may be recorded on a record carrier body, such as a magnetic disk drive, a magnetic tape device, an FD, or a read only memory (ROM). For example, the position circuit 107, the comparison circuit 108, the reference image creation circuit 112, and the like may be configured by at least one processing circuit described above.

The embodiments have been described above with reference to specific examples. However, the invention is not limited to these specific examples.

In addition, the description of parts that are not directly required for the description of the invention, such as the apparatus configuration or the control method, is omitted. However, the required apparatus configuration, control method, and the like can be appropriately selected and used.

In addition, all electron beam mask inspection apparatuses that include the elements of the invention and that can be appropriately modified by those skilled in the art are included in the scope of the invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electron beam mask inspection apparatus, comprising:
a stage, a mask substrate being placed above the stage;
a substrate cover electrode arranged on the mask substrate so as to cover at least a part of an outer periphery of the mask substrate, the substrate cover electrode applying a first potential to the mask substrate from a surface side of the mask substrate;
an objective lens having a surface facing the mask substrate controlled to have a second potential different from the first potential, the objective lens guiding an electron beam onto the mask substrate;
a first electrode plate in which an opening is formed, arranged between the objective lens and the mask substrate, the electron beam passing through the opening;
a mark arranged above the stage so as to be spaced apart from the mask substrate and having a figure pattern formed on its surface; and
a second electrode plate arranged at a height position lower than the first electrode plate and equal to or higher than a height position of the surface of the mask substrate, the second electrode plate being arranged so as to cover a gap between the mask substrate and the mark,
wherein a same potential as the first potential applied to the surface of the mask substrate is applied to the first electrode plate, the mark, and the second electrode plate.

2. The apparatus according to claim 1,
wherein the mark and the second electrode plate are formed separately.

3. The apparatus according to claim 1, further comprising:
a height position measurement sensor configured to measure a surface height of the mask substrate by receiving reflected light from the mask substrate, the reflected light, reflected by the surface of the mask substrate due to a laser light obliquely incident on the mask substrate through the opening of the first electrode plate from between the objective lens and the first electrode plate, traveling between the objective lens and the first electrode plate through the opening.

4. The apparatus according to claim 3, wherein
an inner radius r1 of the first electrode plate in which the opening is formed satisfies, using a distance d from an electron optics central axis to a position where an incident trajectory of the laser light crosses a plane perpendicular to the electron optics central axis at a surface height position of the first electrode plate and a distance a from an edge of the mask substrate to an inspection region of the mask substrate, a relational expression of
$$d < r 1 < a ,$$
an outer radius r2 of the first electrode plate satisfies, using a distance g to a nearest member having a ground potential on the first electrode plate and coefficients b1, b2, and b3, a relational expression of
$$b 1 {g}^{2} + b 2 g + b 3 < r 2 ,$$
and
the opening is formed axially symmetrically with respect to the electron optics central axis.

5. The apparatus according to claim 1,
wherein the mark is formed so that a distance from the second electrode plate to a region where the figure pattern is formed is equal to or greater than a distance from an edge of the mask substrate to a region to be inspected of the mask substrate.

6. The apparatus according to claim 1, further comprising:
a support pillar configured to support the first electrode plate, the support pillar located above the first electrode plate and extending from a member controlled to have the second potential.

7. The apparatus according to claim 3,
wherein an angle θ between an incident trajectory of the laser light and the mask substrate surface satisfies, using a distance a from an edge of the mask substrate to an inspection region of the mask substrate, a thickness t of the first electrode plate, and a gap c between the first electrode plate and the mask substrate surface, a relational expression of
$$arctan \{ ( t + c ) / a \} < θ .$$

8. The apparatus according to claim 1,
wherein an inspection region of the mask substrate is rectangular, and
the substrate cover electrode has:
a frame arranged on the mask substrate so as not to overlap the mask substrate on a short side of the inspection region and so as to partially overlap an outer periphery of the mask substrate on a long side of the inspection region; and
a plurality of conductive pins arranged on the frame and in contact with the mask substrate.

9. The apparatus according to claim 8,
wherein the frame is formed in a rectangular shape, and
the plurality of conductive pins are arranged on a long side of the frame.

10. The apparatus according to claim 9,
wherein a surface height position of the frame on a long side of the substrate cover electrode is higher than a surface height of the mask substrate, and a surface height position of the frame on a short side of the substrate cover electrode is lower on a surface height side of the mask substrate than the height position of the frame on the long side.

11. The apparatus according to claim 6,
wherein, as the member, the objective lens is included.

12. The apparatus according to claim 6, further comprising:
a heat shield arranged between the objective lens and the first electrode plate and functioning as the member.
